(19) United States
(12) Patent Application Publication
(10) Pub. No.: US 2009/0091380 A1
(43) Pub. Date: Apr. 9, 2009

(54) DIFFERENTIAL VARACTOR USING GATED VARACTOR

(75) Inventors: BYUNG HUN MIN, Jeollabuk-do (KR); YOUNG HO KIM, Daejeon (KR); KYUNG HWAN PARK, Daejeon (KR); SEOK BONG HYUN, Daejeon (KR)

Correspondence Address: AMPACC LAW GROUP, 13024 Beverly Park Road, Suite 205, Mukilteo, WA, 98275, US

(73) Assignee: Electronics and Telecommunications Research Institute, Daejeon (KR)

(21) Appl. No.: 12/195,223

(22) Filed: Aug. 20, 2008

(30) Foreign Application Priority Data
Oct. 5, 2007 (KR) 10-2007-0100608

(51) Int. Cl. H01L 29/93

(52) U.S. Cl. 327/586

(57) ABSTRACT

Provided is a differential varactor using a gated varactor, which has a wider tuning range and a better linearity and minimum to maximum capacitance ratio than conventional PN-junction and MOS varactors. Thus, the differential varactor having a wider tuning range, and better linearity and common-mode rejection ratio may be implemented.

### CROSS-REFERENCE TO RELATED APPLICATION

This application claims priority to and the benefit of Korean Patent Application No. 2007-100608 filed Oct. 5, 2007, the disclosure of which is incorporated herein by reference in its entirety.

### BACKGROUND

1. Field of the Invention

The present invention relates to a differential varactor using a gated varactor, and more particularly, to a differential varactor using a gated varactor having a wide tuning range and good linearity.

This work was supported by the IT R&D program of MIC/IITA[2005-S-017-03, Integrated Development of Ultra Low Power RF/HW/SW SoC].

2. Discussion of Related Art

Generally, a varactor is a device having a reactance component (capacitance) varying with an applied voltage or current source. The reactance component depends on a width of a depletion layer varying with the size of applied reverse bias.

Such varactors are widely used in control circuits and voltage controlled oscillators (VCO). Among these, PN-junction varactors D₁ to D₄ as illustrated in FIG. 1A and MOS varactors M₁ to M₄ as illustrated in FIG. 1B are used for differential VCOs.

However, since the PN-junction varactors D₁ to D₄ have good linearity but a narrow frequency tuning range, they have limitations as frequency tuning devices of the VCOs. Further, since the MOS varactors M₁ to M₄ have a relatively wide tuning range but poor linearity, they have a low common-mode rejection ratio (CMRR) when they are designed in a differential type.

### SUMMARY OF THE INVENTION

The present invention is directed to implementation of a differential varactor having a wide tuning range, good linearity and an improved common-mode rejection ratio.

One aspect of the present invention is to provide a differential varactor using a gated varactor, including: first and second input terminals for receiving a differential signal; first and third gated varactors commonly connected to the first input terminal; and second and fourth gated varactors commonly connected to the second input terminal, the second and fourth gated varactors being connected to the first and third gated varactors, respectively, wherein a total capacitance of the first to fourth gated varactors has a predetermined slope in a differential mode, and a constant value in a common mode, according to the change of a control voltage.

Another aspect of the present invention is to provide a differential varactor using a gated varactor, including: first and second input terminals for receiving a differential signal; first and third gated varactors having source electrodes to be commonly connected to the first input terminal; and second and fourth gated varactors having source electrodes to be commonly connected to the second input terminal, the second and fourth gated varactors being connected to the first and third gated varactors, respectively, wherein a total capacitance of the first to fourth gated varactors has a predetermined slope in a differential mode, and a constant value in a common mode, according to the change of a control voltage.

### BRIEF DESCRIPTION OF THE DRAWINGS

The above and other objects, features and advantages of the present invention will become more apparent to those of ordinary skill in the art by describing in detail preferred embodiments thereof with reference to the attached drawings in which:

FIG. 1A is a circuit diagram of a conventional differential varactor using a PN-junction varactor, and FIG. 1B is a circuit diagram of a conventional differential varactor using a MOS varactor;

FIG. 2A is a cross-sectional view of a gated varactor formed on an n-type well in a Triple-well process, and FIG. 2B is a cross-sectional view of a gated varactor formed on a p-type well in a Triple-well process;

FIGS. 3A and 3B illustrate the gated varactors of FIGS. 2A and 2B using circuit symbols;

FIG. 4A is a circuit diagram of a differential varactor using a gated varactor according to a first exemplary embodiment of the present invention, and FIG. 4B is a circuit diagram of a differential varactor using a gated varactor according to a second exemplary embodiment of the present invention;

FIG. 5 is a circuit diagram of an LC voltage controlled oscillator using a differential varactor according to the present invention; and

FIG. 6 is a graph illustrating oscillation frequencies of the LC voltage controlled oscillator illustrated in FIG. 5 in a common mode and a differential mode.

### DETAILED DESCRIPTION OF EXEMPLARY EMBODIMENTS

Hereinafter, the present invention will be described in detail with reference to the accompanying drawings.

Before the explanation of the present invention, the following should be noted. It has been disclosed in the Journal of Solid-state Circuits (W. M. Y Wong; A Wide Tuning Range Gated Varactor; May 2000) that a gated varactor is superior to conventional PN-junction and MOS varactors in tuning range, linearity, and minimum to maximum capacitance ratio.

According to the results of such research, the present invention implements a differential varactor having a wide tuning range, good linearity and an improved common-mode rejection ratio (CMRR) using a gated varactor, which will be described in detail with reference to the accompanying drawings.

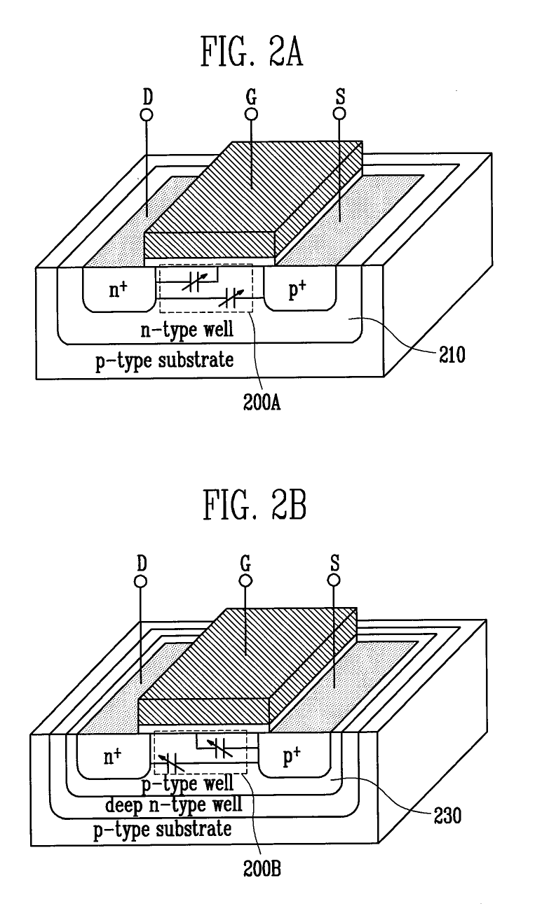

FIG. 2A is a cross-sectional view of a gated varactor formed on an n-type well in a Triple-well process, and FIG. 2B is a cross-sectional view of a gated varactor formed on a p-type well in a Triple-well process.

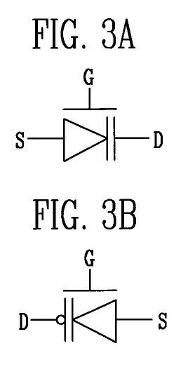

Referring to FIGS. 2A and 2B, gated varactors 200A and 200B formed on n− and p-type wells 210 and 230 include a polysilicon-on-oxide region or a metal-on-oxide region defined as a gate electrode G, an n+-doped region defined as a drain electrode D, and a p+-doped region defined as a source electrode S. The gated varactors 200A and 200B are illustrated using circuit symbols in FIGS. 3A and 3B, respectively.

An n⁺n⁻p⁺-doped region is formed between the drain electrode D and the source electrode S of the gated varactor 200A on the n-type well 210. And, an n⁺p⁻p⁺-doped region is formed between the drain electrode D and the source electrode S of the gated varactor 200B on the p-type well 230.

The gated varactor 200A on the n-type well 210 has a MOS varactor characteristic using an accumulation mode and a depletion mode between the gate electrode G and the drain electrode D, and a capacitance of a PN junction varactor characteristic between the source electrode S and the drain electrode D.

The gated varactor 200B on the p-type well 230 has a MOS varactor characteristic using the accumulation mode and the depletion mode between the gate electrode G and the source electrode S, and a capacitance of a PN-junction varactor characteristic between the source electrode S and the drain electrode D.

That is, the gated varactors 200A and 200B have both the MOS varactor characteristic using the depletion and accumulation modes and the PN-junction varactor characteristic, and thus a total capacitance (Cₜₒₜₐₗ) of each gated varactor 200A or 200B may be expressed by Formula 1.

Cₜₒₜₐₗ=Cᵥₐᵣ+C_{junction}+C_{parasitic} [Formula 1]

In Formula 1, Cᵥₐᵣ is a capacitance of a MOS varactor using an accumulation mode, C_{junction} of is a junction capacitance according to PN junction, and C_{parasitic} is a parasitic capacitance.

The differential varactor including such gated varactors 200A and 200B can have a wider tuning range and a better linearity and CMRR than a conventional differential varactor, by setting bias between terminals of each varactor so that capacitance slopes of the PN-junction characteristic and the MOS varactor characteristic of the gated varactors 200A and 200B have the same negative or positive direction. This will be described below in detail.

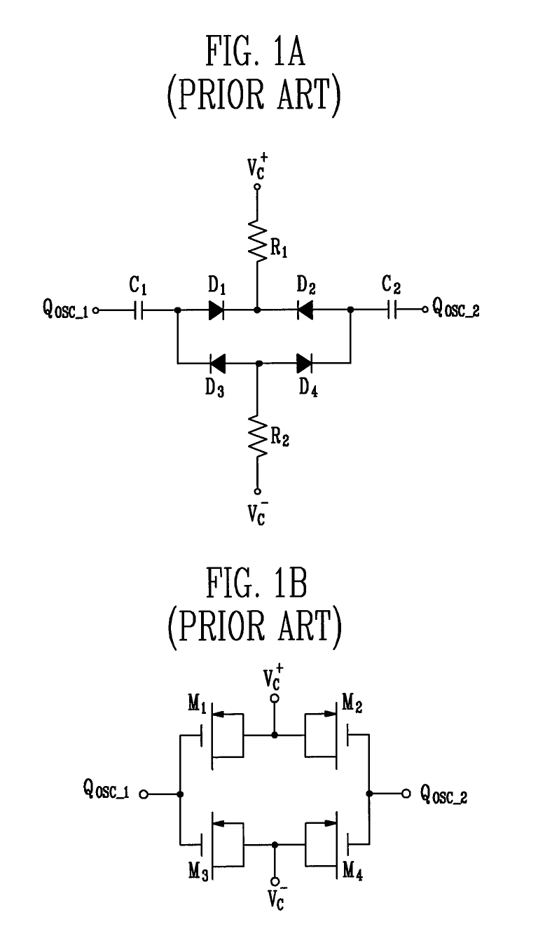

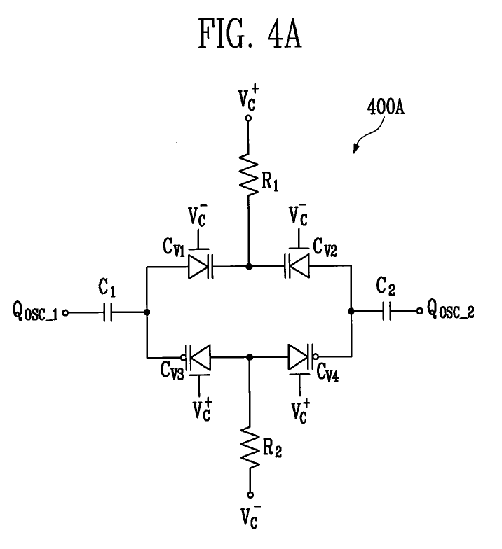

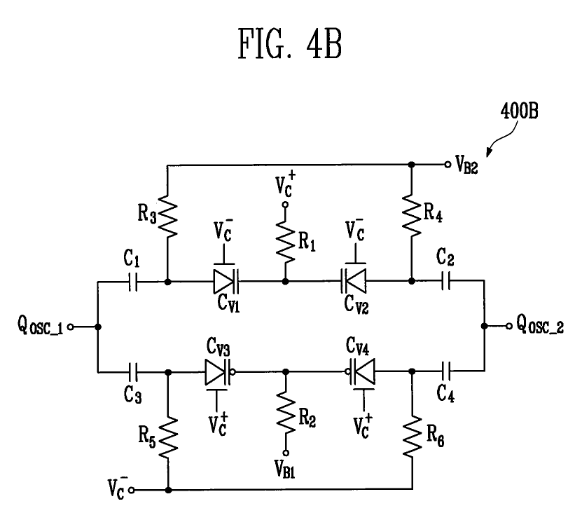

FIG. 4A is a circuit diagram of a differential varactor using a gated varactor 400A according to a first exemplary embodiment of the present invention, wherein the differential varactor has gated varactors Cv1 to Cv4, instead of the PN-junction varactors D₁ to D₄ in the differential varactor circuit of FIG. 1A.

First, connections between elements of the differential varactor will be described.

First and third gated varactors Cv1 and Cv3 are commonly connected to a first input terminal Q_{OSC}_{_{—}}₁ for a differential signal through a first capacitor C₁, and second and fourth gated varactors Cv2 and Cv4 are commonly connected to a second input terminal Q_{OSC}_{_{—}}₂ for a differential signal through a second capacitor C₂.

Here, the first and second gated varactors Cv1 and Cv2 are gated varactors formed on an n-type well, and the third and fourth gated varactors Cv3 and Cv4 are gated varactors formed on a p-type well.

A negative power voltage V_{C}⁻ is applied to gate electrodes of the first and second gated varactors Cv1 and Cv2, and a positive power voltage V_{C}⁺ is applied to drain electrodes connected with each other, through a first resistor R₁.

In addition, the positive power voltage V_{C}⁺ is applied to gate electrodes of the third and fourth gated varactors, and the negative power voltage V_{C}⁻ is applied to source electrodes connected with each other, through a second resistor R₂.

In the differential varactor 400A, a total capacitance C_{total,diff} applied to an oscillation node may be expressed by Formula 2.

C_{total,diff}=C_{var,N}+C_{junction,N}+C_{var,P}+C_{junction,P}+Cₚₐᵣₐ [Formula 2]

In Formula 2, C_{var,N} and C_{junction,N} are a MOS varactor capacitance and a PN-junction varactor capacitance of the first and second gated varactors, and C_{var,P} and C_{junction,P} are a MOS varactor capacitance and a PN-junction capacitance of the third and fourth gated varactors Cv3 and Cv4. Cₚₐᵣₐ is a parasitic capacitance of the first to fourth gated varactors Cv1, Cv2, Cv3 and Cv4.

Operational characteristics of the differential varactor 400A are divided into differential-mode and common-mode operations. The differential mode operation will now be described.

When V_{C}⁺>>V_{C}⁻ in the first and third gated varactors Cv1 and Cv3 or the second and fourth gated varactors Cv2 and Cv4, a PN-junction depletion layer between the source electrode and the drain electrode gets thicker, and a MOS varactor between the gate electrode and the drain electrode becomes in a depletion mode. Thus, the total capacitance of the differential varactor 400A becomes smaller.

Contrarily, when V_{C}⁺<<V_{C}⁻, the PN-junction depletion layer gets thinner due to forward biasing, and the MOS varactor becomes in an accumulation mode. Thus, the total capacitance of the differential varactor 400A becomes larger.

Even when the forward bias is applied by an internally generated potential at the PN junction, there is no current flow from V_{C}⁻ to V_{C}⁺ as long as the potential does not reach a certain level or more.

For the common-mode operation of the differential varactor 400A, when V_{C}⁺=V_{C}⁻, the first to fourth gated varactors Cv1, Cv2, Cv3 and Cv4 have an equal potential at the gate, source and drain electrodes. Thus, there is no change in the total capacitance of the differential varactor 400A when the common-mode voltage changes.

That is, the differential varactor 400A in FIG. 4A has a wider tuning range and better linearity than the conventional differential varactor, because the total capacitance of the first to fourth gated varactors Cv1, Cv2, Cv3 and Cv4 has a predetermined slope in a differential mode and a constant value in a common mode when the control voltage changes.

However, when V_{C}⁺=V_{C}⁻, the first to fourth gated varactors Cv1, Cv2, Cv3 and Cv4 may be forward-biased, which obstructs the common-mode operation.

To prevent the PN junction from being forward-biased, the drain and source electrodes of the first and third gated varactors Cv1 and Cv3 and the second and fourth gated varactors Cv2 and Cv4 are designed to have the same direction, which will be now described in detail.

FIG. 4B is a circuit diagram of a differential varactor 400B using a gated varactor according to a second exemplary embodiment of the present invention. It can be seen that drain and source electrodes of first and third gated varactors Cv1 and Cv3 and the second and fourth gated varactors Cv2 and Cv4 are designed to have the same direction for improved symmetricity, unlike the differential varactor 400A illustrated in FIG. 4A.

Since the differential varactor 400B has basically the same circuit configuration as the differential varactor 400A of FIG. 4A, only additional and modified elements and their connections will now be described.

First, in the differential varactor 400B of FIG. 4B, source electrodes of the first and third gated varactors Cv1 and Cv3 are commonly connected to a first input terminal Q_{OSC1} for a differential signal through first and third capacitors C₁ and C₃. And, source electrodes of the second and fourth gated varactors Cv2 and Cv4 are commonly connected to a second input terminal Q_{OSC2} for a differential signal through second and fourth capacitors C₂ and C₄.

In addition, a positive bias voltage V_{B2} is applied to the source electrodes of the first and second gated varactors Cv1 and Cv2 through third and fourth resistors R₃ and R₄, and a negative power voltage V_{C}⁻ is applied to the source electrodes of the third and fourth gated varactors Cv3 and Cv4 through fifth and sixth resistors R₅ and R₆. A negative bias voltage V_{B1} is applied to drain electrodes, which are connected with each other, of the third and fourth gated varactors Cv3 and Cv4 through a second resistor R₂.

In the differential varactor 400B formed as described above, the positive bias voltage V_{B2} and a positive power voltage V_{C}⁺ are applied to the source and drain electrodes of the first and second gated varactors Cv1 and Cv2, and the negative power voltage V_{C}⁻ and a negative bias voltage V_{B1} are applied to the source and drain electrodes of the third and fourth gated varactors Cv3 and Cv4, respectively. This can prevent the PN junctions of the first and second gated varactors Cv1 and Cv2 and the third and fourth gated varactors Cv3 and Cv4 from being forward-biased.

Operational characteristics of the differential varactor 400B are also divided into differential-mode and common-mode operations. The differential-mode operation will now be described.

When V_{B1}>V_{C}⁺>>V_{C}⁻>V_{B2} in the first and third gated varactors Cv1 and Cv3 or the first and second gated varactors Cv2 and Cv4, a depletion layer of the PN junction gets thicker and a MOS varactor becomes in a depletion mode. Thus, a total capacitance of the differential varactor 400B becomes smaller.

When V_{B1}>V_{C}⁻>>V_{C}⁺>V_{B2}, the depletion layer of the PN junction gets thinner and the MOS varactor becomes in an accumulation mode. Thus, a capacitance value of the differential varactor 400B becomes larger.

In addition, for the common-mode operation, When V_{B1}>V_{C}⁺=V_{C}⁻>V_{B2}, gate and drain electrodes of the first and second gated varactors Cv1 and Cv2 have an equal potential to each other, and gate and source electrodes of the third and fourth gated varactors Cv3 and Cv4 have an equal potential to each other. Thus, there is no change in total capacitance of the differential varactor 400B.

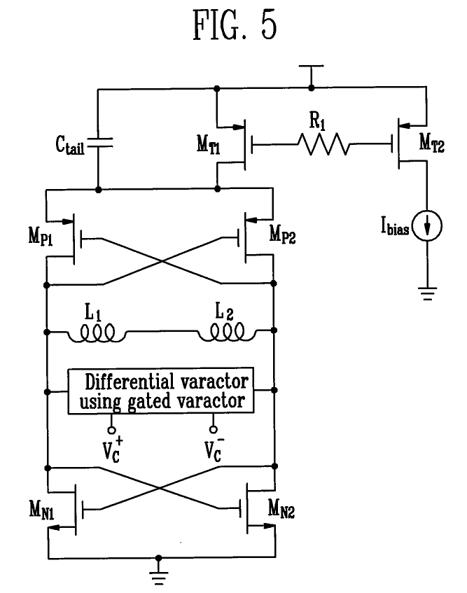

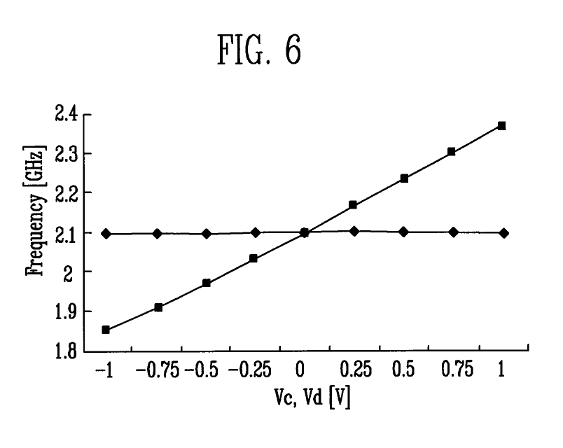

FIG. 5 is a circuit diagram of an LC voltage-controlled oscillator using a differential varactor according to the present invention, and FIG. 6 is a graph illustrating oscillation frequency characteristics of an LC voltage-controlled oscillator of FIG. 5 in a common mode and a differential mode. Here, either the differential varactor 400A in FIG. 4A or the differential varactor 400B in FIG. 4B may be used.

In the LC voltage-controlled oscillator, a CMRR may be expressed by Formula 3.

$$CMRR = 20 \cdot log \frac{{K}_{v}}{{K}_{vCM}} \qquad [ Formula 3 ]$$

In Formula 3, Kᵥ is a change in a frequency according to a change in a differential-mode control voltage, and K_{vCM} is a change in a frequency according to a change in a common-mode control voltage.

It can be seen that, by implementing the LC voltage controlled oscillator using the differential varactor having a gated varactor with good linearity, the LC voltage controlled oscillator can have an about 30 dB higher CMRR than the conventional LC voltage controlled oscillator using a PN-junction varactor or a MOS varactor, as shown in FIG. 6.

According to the present invention, the differential varactor having an improved CMRR can be implemented by the differential varactor using a gated varactor with a wider tuning range, and better linearity and a minimum to maximum capacitance ratio than a conventional PN-junction varactor and a MOS varactor.

Moreover, an LC voltage controlled oscillator with good linearity of an oscillation frequency to a control voltage can be implemented by the differential varactor using the gated varactor.

While the invention has been shown and described with reference to certain exemplary embodiments thereof, it will be understood by those skilled in the art that various changes in form and details may be made therein without departing from the spirit and scope of the invention as defined by the appended claims. Therefore, the disclosed embodiments are to be considered in a descriptive aspect, not a definitive aspect. The scope of the present invention has been shown by the appended claims, not by the above descriptions, and it will be understood that all differences in the equivalent scope thereto are included in the present invention.

What is claimed is:

1. A differential varactor using a gated varactor, comprising:
first and second input terminals for receiving a differential signal;
first and third gated varactors commonly connected to the first input terminal; and
second and fourth gated varactors commonly connected to the second input terminal, the second and fourth gated varactors being connected to the first and third gated varactors, respectively,
wherein a total capacitance of the first to fourth gated varactors has a predetermined slope in a differential mode and a constant value in a common mode, according to the change of a control voltage.

2. The differential varactor according to claim 1, wherein the first and second gated varactors are gated varactors formed on an n-type well, and the third and fourth gated varactors are gated varactors formed on a p-type well.

3. The differential varactor according to claim 1, wherein drain electrodes of the first and second gated varactors are connected with each other, and source electrodes of the third and fourth gated varactors are connected with each other.

4. The differential varactor according to claim 1, wherein a negative power voltage is applied to gate electrodes of the first and second gated varactors, and a positive power voltage is applied to drain electrodes of the first and second gated varactors through a first resistor.

5. The differential varactor according to claim 1, wherein a positive power voltage is applied to gate electrodes of the third and fourth gated varactors, and a negative power voltage is applied to source electrodes of the third and fourth gated varactors through a second resistor.

6. The differential varactor according to claim 1, wherein a bias voltage is set in a differential mode so that capacitance slopes of a PN-junction characteristic and a MOS varactor characteristic of the first to fourth gated varactors have the same negative or positive direction.

7. The differential varactor according to claim 1, wherein first and second capacitors are connected to the first and second input terminals, respectively.

8. A differential varactor using a gated varactor, comprising:
first and second input terminals for receiving a differential signal;
first and third gated varactors having source electrodes commonly connected to the first input terminal; and
second and fourth gated varactors having source electrodes commonly connected to the second input terminal, the second and fourth gated varactors being connected to the first and third gated varactors, respectively,
wherein a total capacitance of the first to fourth gated varactors has a predetermined slope in a differential mode and a constant value in a common mode, according to the change of a control voltage.

9. The differential varactor according to claim 8, wherein the first and second gated varactors are gated varactors formed on an n-type well, and the third and fourth gated varactors are gated varactors formed on a p-type well.

10. The differential varactor according to claim, 8, wherein drain electrodes of the first and second gated varactors are connected with each other, and drain electrodes of the third and fourth gated varactors are connected with each other.

11. The differential varactor according to claim 8, wherein a negative power voltage is applied to gate electrodes of the first and second gated varactors, a positive power voltage is applied to drain electrodes through a first resistor, and a positive bias voltage is applied to source electrodes through third and fourth resistors.

12. The differential varactor according to claim 8, wherein a positive power voltage is applied to gate electrodes of the third and fourth gated varactors, a negative bias voltage is applied to drain electrodes through a second resistor, and a negative power voltage is applied to source electrodes through fifth and sixth resistors.

13. The differential varactor according to claim 8, wherein a bias voltage is set in a differential mode so that capacitance slopes of a PN-junction characteristic and a MOS varactor characteristic of the first to fourth gated varactors have the same negative or positive direction.

14. The differential varactor according to claim 8, wherein first and third capacitors are connected to the first input terminal, and second and fourth capacitors are connected to the second input terminal.
